(19) United States
(12) Patent Application Publication
(10) Pub. No.: US 2012/0107639 A1
(43) Pub. Date: May 3, 2012

(54) ELECTRICAL COMPONENT AND METHOD FOR MANUFACTURING ELECTRICAL COMPONENTS

(75) Inventors: Masao Takamizawa, Okayama (JP); Toshihide Naka, Okayama (JP); Hitoshi Kemmotsu, Okayama (JP); Yoshiyuki Nishimura, Okayama (JP)

(73) Assignee: OM SANGYO CO., LTD., Okayama-shi (JP)

(21) Appl. No.: 13/380,641

(22) PCT Filed: Apr. 30, 2010
(86) PCT No.: PCT/JP2010/057697

§ 371 Date: Dec. 23, 2011

(30) Foreign Application Priority Data
Jun. 29, 2009 (JP) 2009-154356

(51) Int. Cl. B05D 5/12; H01L 29/12; C23C 28/02

(52) U.S. Cl. 428/620; 205/191; 427/125

(57) ABSTRACT

An electrical component is provided by a method comprising forming a middle plated layer made of palladium or a palladium alloy on a substrate and forming a surface plated layer made of tin or a tin alloy containing a metal other than palladium on the middle plated layer. Thus, there can be provided an electrical component having a surface layer consisting primarily of tin in which whisker formation can be prevented for a long period under stress.

### TECHNICAL FIELD

The present invention relates to an electrical component having a plated layer made of tin or a tin alloy on the surface of a substrate and a manufacturing method therefor. In particular, the present invention relates to an electrical component such as a terminal, a connector and a flexible substrate for flip-chip mounting and a manufacturing method therefor, in which whisker formation from the plated layer can be prevented.

### BACKGROUND ART

Generally, an alloy consisting primarily of tin is plated on the surface of an electrical component such as a terminal, a connector, a lead frame in a semiconductor integrated circuit for preventing oxidation, reducing a contact resistance and improving solderability. Such an alloy for plating has been suitably a tin-lead alloy. However, needs for lead-free electrical and electronic components have accelerate investigations for plating with tin alone or a lead-free alloy such as tin-silver, tin-bismuth and tin-copper. There has been, however, a problem that tin or a tin alloy without lead tends to form a whisker from a plated film and a grown whisker may cause short circuit.

For preventing such whisker formation, there is a known process in which a plated film made of a tin alloy is formed and then reflowing of the film is conducted (see, for example, Patent Reference Nos. 1 and 2). A conventional heating process may, however, form an excessively thick diffusion layer between a superficial tin plated film and a base layer, leading to marked variation in quality of a resulting electrical component. Furthermore, heating may reduce solderability of the tin plated film.

For preventing such whisker formation, there has been disclosed a process in which a metal film such as bismuth, silver and nickel is formed on a material to be plated as a base layer, and a plated film made of tin or a tin alloy is then formed on the metal layer (see, for example, Patent Reference No. 3). There has been also disclosed a method, for example, in a film carrier having a fine pattern of copper or a copper alloy coated by a solder resist, for preventing formation of a whisker from a tin plating on the fine pattern. In the method, a base film made of a single metal such as bismuth, silver and nickel is formed and heated, and then a tin film is formed (see, for example, Patent Reference No. 4). There has been, however, a problem that when a metal as described above is used as a base film, whisker formation cannot be prevented for a long period under external stress and heating causes significant variation in properties.

There has been also disclosed a method in which for preventing whisker from growing, an intermetallic compound of tin and another metal is formed in a tin or tin-alloy crystal grain boundary in a tin or tin-alloy film (see, for example, Patent Reference No. 5). There has been also disclosed a method in which a material to be plated is immersed in a pretreatment liquid which is a known etchant containing a metal ion having a positive potential compared to copper and thereafter, tin or tin-alloy plating is formed (see, for example, Patent Reference No. 6). However, when any of these methods of the prior art is employed, properties of a resulting electrical component may vary by scattering another metal in a tin or tin-alloy crystal grain boundary or by etching of a material to be plated. Furthermore, whisker formation cannot be satisfactorily prevented under external stress on an electrical component.

### PATENT REFERENCES

Patent Reference 1: JP 2002-69688 A
Patent Reference 2: JP 2003-193289 A
Patent Reference 3: JP 2003-129278 A
Patent Reference 4: JP 2003-332391 A
Patent Reference 5: WO 2006/134665 A1
Patent Reference 6: JP 2006-213938 A

### SUMMARY OF THE INVENTION

### Problem to be Solved by the Invention

For solving the above problems, an objective of the present invention is to provide an electrical component having a surface layer consisting primarily of tin in which whisker formation can be prevented for a long period under stress.

### Means for Solving the Problems

After investigation for solving the above problems, we have found that in an electrical component having a surface layer made of tin or a tin alloy in a substrate surface, whisker formation can be prevented for a long period even under stress by forming a middle layer consisting primarily of palladium under the surface layer, and have thus achieved the present invention.

Specifically, the present invention provides a method for manufacturing an electrical component, comprising: forming a middle plated layer made of palladium or a palladium alloy on a substrate, and forming a surface plated layer made of tin or a tin alloy containing a metal other than palladium on the middle plated layer. Here, the middle plated layer preferably has a thickness of 0.02 to 2 μm. It is also preferable to form the middle plated layer by electrolytic plating. It is also preferable that the substrate is made of a material containing copper.

Preferably, the manufacturing method of the present invention further comprises heating after forming the surface plated layer. Here, the heating is preferably reflowing or alternatively annealing. Preferably, the method further comprises forming a base plated layer consisting primarily of nickel or copper on the substrate before forming the middle plated layer.

Furthermore, the present invention provides an electrical component comprising a substrate, a middle layer made of palladium or a palladium alloy on the substrate, and a surface layer made of tin or a tin alloy containing a metal other than palladium formed on the middle layer. In the electrical component of the present invention, the middle layer preferably has a thickness of 0.02 to 2 μm. Furthermore, the electrical component of the present invention preferably has a base layer consisting primarily of nickel or copper under the middle layer.

Furthermore, the present invention provides an electrical component comprising a substrate and a surface layer formed on the substrate, wherein the surface layer comprises a phase made of tin or a tin alloy containing a metal other than palladium and an alloy phase containing tin and palladium. Preferably, the electrical component of the present invention comprises a middle layer made of palladium or a palladium alloy under the surface layer. It is also preferable that the middle layer has a thickness of 0.02 to 2 μm. Furthermore, the electrical component of the present invention preferably has a base layer consisting primarily of nickel or copper under the surface layer.

In the electrical component of the present invention, it is preferable that the substrate is made of a material containing copper. Furthermore, it is preferable that in a cross-section orthogonal to the substrate surface in the surface layer, there exists a continuous region with an interparticle crystal misorientation of 15° or less extending over 10 μm or more in crystal orientation distribution of tin as determined by Electron Backscatter Diffraction (EBSD).

### Effects of the Invention

In accordance with the present invention, there can be provided an electrical component having a surface layer consisting primarily of tin, in which whisker formation can be prevented for a long period even under stress.

### BRIEF DESCRIPTION OF THE DRAWINGS

FIG. 1 is a partial cross-sectional view showing a first embodiment of an electrical component of the present invention.

FIG. 2 is a partial cross-sectional view showing a second embodiment of an electrical component of the present invention.

FIG. 3 is an SIM image of a cross-section of a tape obtained in Example 1.

FIG. 4 is an SIM image of a cross-section of a tape obtained in Example 2.

FIG. 5 is (a) an SIM image and (b) an X-RAY diffraction chart of a cross-section of a tape obtained in Example 3.

FIG. 6 is a crystal orientation map for a tape obtained in Example 15.

FIG. 7 is a crystal orientation map for a tape obtained in Example 16.

### BEST MODE FOR CARRYING OUT THE INVENTION

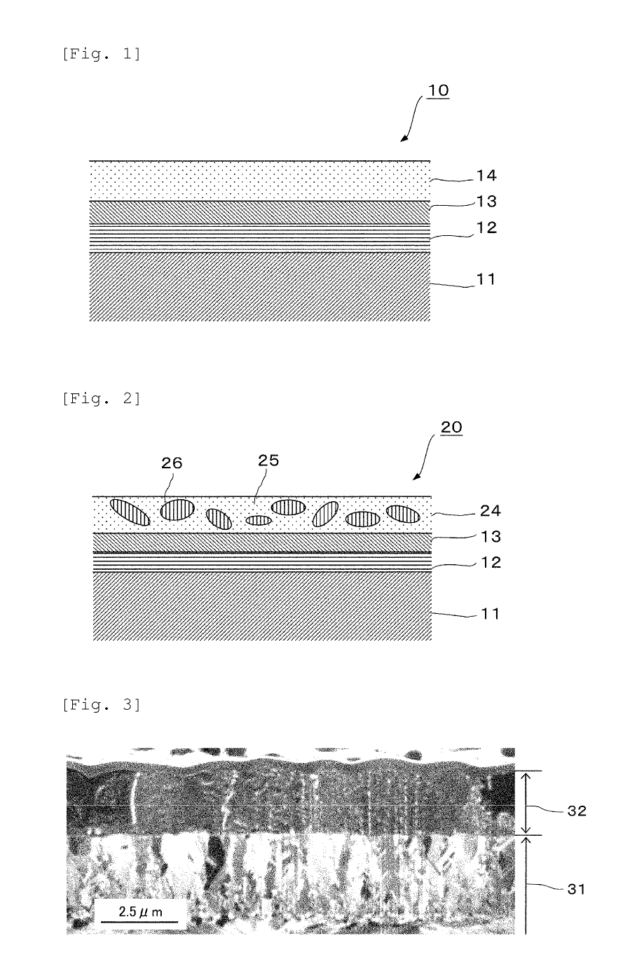

First, there will be described a method for manufacturing an electrical component of the present invention with reference to the drawings. FIG. 1 is a partial cross-sectional view of one embodiment of an electrical component obtained by a manufacturing method of the present invention. The electrical component 10 in FIG. 1 has a substrate 11, a base layer 12 formed on the substrate, a middle layer 13 and a surface layer 14. A method for manufacturing an electrical component of the present invention has forming a middle plated layer made of palladium or a palladium alloy on a substrate and forming a surface plated layer made of tin or a tin alloy containing a metal other than palladium on the middle plated layer.

A substrate can be made of any material for a desired product. A substrate for an electrical component is generally a conductive metal material. For an electrical component such as a terminal, a connector and a lead frame for an IC, a substrate is suitably copper or an alloy consisting primarily of copper. Alternatively, a substrate can be a conductive foil made of, for example, copper or an alloy consisting primarily of copper formed on a thin base film made of glass epoxy or polyimide such as a flexible printed board. Here, the expression “consisting primarily of” refers to containing a given component in 50% by weight or more.

First, on a substrate is formed a middle plated layer made of palladium or a palladium alloy. A base plated layer can be, if necessary, formed on a substrate before the middle plated layer is formed. A material for the base plated layer is appropriately selected for an application of an electrical component and is preferably at least one metal selected from the group consisting of copper, nickel and silver or an alloy consisting primarily of any of these metals. Here, the expression “consisting primarily of” refers to containing a component in 50% by weight or more. A base plated layer can be a monolayer or a laminate of two or more layers.

There are no particular restrictions to a thickness of the base plated layer formed (plating thickness) which is appropriately determined depending on a thickness of another plated layer, required electric properties of an electrical component and the like. For achieving required functions of the base layer while reducing material costs, the base plated layer preferably has a thickness of 0.5 to 3 μm.

A middle plated layer can be made of palladium alone or a palladium alloy. It is preferably made of palladium alone for uniformly dispersing palladium in a tin phase by forming an alloy of tin and palladium in a surface plated layer described later. A palladium alloy used for a middle plated layer denotes an alloy containing palladium as a main component and one or more other metals. A content of palladium in the palladium alloy is generally 50% by weight or more, preferably 60% by weight or more, more preferably 70% by weight or more.

A plating thickness of a middle plated layer is appropriately determined depending on a thickness of a surface layer, heating conditions, required electric properties of an electrical component and the like, and is preferably 0.02 to 2 μm. A plating thickness of a middle plated layer within the above range allows palladium to be dispersed in a surface plated layer to such an extent that whisker formation can be satisfactorily prevented. If a plating thickness of a middle plated layer is less than the above range, palladium contributing to formation of an alloy with tin in the surface plated layer may be insufficient to satisfactorily prevent whisker formation. In the light of such a situation, a plating thickness of a middle plated layer is more preferably 0.03 μm or more, further preferably 0.04 μm or more. Meanwhile, a plating thickness of a middle plated layer more than the above range cannot contribute to further improvement in preventing whisker formation, and leads to increase in the amount of palladium used in forming the middle plated layer, which is undesirable in terms of cost. In the light of such a situation, a plating thickness of a middle plated layer is preferably 1 μm or less, further preferably 0.5 μm or less.

On the middle plated layer is formed a surface plated layer made of tin or a tin alloy containing a metal other than palladium. The tin alloy used for the surface plated layer denotes an alloy containing tin as a main component and one or more other metal components. Suitably, it can be a combination such as, but not limited to, tin-silver, tin-bismuth and tin-copper. A content of tin in the tin alloy is generally 50% by weight or more, preferably 60% by weight or more, more preferably 70% by weight or more. Here, the expression “containing a metal other than palladium” denotes that the alloy has a composition substantially free from palladium, but the alloy may contain a trace amount of palladium as an impurity. Furthermore, the use of lead in electric/electronic devices has been regulated due to concerns about adverse affect on the human body and the natural environment, and the present invention aims at preventing whisker formation in a lead-free tin plated film. It is, therefore, preferable that the tin alloy is substantially free from lead.

A thickness of a surface plated layer can be appropriately selected depending on the size, an application, required performance and the like of an electrical component, and is preferably 0.2 to 15.0 μm. An excessively thin surface plated layer is undesirable because a surface layer containing a tin-palladium alloy phase as described later may not be formed or a diffusion layer formed by heating reaches the surface of the surface layer so that desired electrical properties cannot be achieved. A thickness of the surface plated layer is preferably 0.5 μm or more, further preferably 1.0 μm or more. Meanwhile, if the surface plated layer is too thick, a proportion of a tin-palladium alloy phase in the surface layer becomes too small to achieve prevention of whisker formation. Furthermore, it is undesirable because the needs for size reduction in an electrical component produced cannot be met. A thickness of the surface plated layer is preferably 10.0 μm or less, furthermore 5.0 μm or less.

There are no particular restrictions to a plating method in forming a base plated layer, a middle plated layer and a surface plated layer, and a known method such as electrolytic plating and non-electrolytic plating can be employed. Furthermore, before or after forming each plated layer, processing such as degreasing, washing, etching and drying can be appropriately conducted.

In a method for manufacturing an electrical component of the present invention, it is preferable that heating is conducted after forming a surface plated layer. Examples of a heating method include reflowing where a substrate on which a surface plated layer has been formed is placed in a heating furnace such as a reflow oven followed by tin melting; annealing where the substrate is heated at a temperature lower than a melting point of tin; and laser reflowing where the surface of a surface plated layer is irradiated with laser beam. During a process involving soldering such as forming a connector or a lead frame in an IC chip, reflowing can be simultaneously conducted. The term “reflowing” as used herein includes melting of tin in a surface plated layer in a heating furnace without soldering. For producing a flexible wiring substrate, annealing for endowing a conductive foil with flexibility can simultaneously anneal the surface plated layer.

The above heating can promote diffusion of elemental palladium in the middle plated layer into the surface plated layer, so that a surface layer containing a tin-palladium alloy phase can be efficiently formed. As detailed later, heating can be effective in aligning crystal orientation of tin particles in the surface layer to some extent. Thus, an energy gradient within a crystal particle and a crystal grain boundary in the surface layer can be alleviated, so that whisker formation is expected to be more effectively prevented.

The heating conditions are appropriately chosen, depending on a heating method, the type and the shape of an electrical component obtained, a thickness of each plated layer and the like. For example, in the reflowing, heating is preferably conducted at a temperature of a melting point of tin or the above tin alloy or higher. The upper limit of the heating temperature is generally about 400° C. A heating time in the reflowing is preferably 0.3 to 120 sec. If a reflow temperature is too low or a heating time is too short, elemental palladium cannot be adequately dispersed into the surface plated layer, so that a surface layer or a middle layer in the present invention might not be formed. If a reflow temperature is too high or a heating time is too long, a metal constituting a base plated layer or substrate diffuses to the surface of a surface layer and may adversely affect electric properties of an electrical component obtained. It is also undesirable in terms of an energy cost.

When annealing is employed, heating is preferably conducted at a temperature lower than a melting point of tin or the above tin alloy. The lower limit of a heating temperature is generally about 80° C. A heating time for the annealing is preferably 30 sec to 180 min. If an annealing temperature is too low or a heating time is too short, elemental palladium cannot be adequately dispersed into the surface plated layer, so that a surface layer or a middle layer in the present invention might not be formed. A too high reflow temperature or a too long heating time may adversely affect electric properties of an electrical component obtained. It is also undesirable in terms of an energy cost.

Thus, by forming the surface plated layer on the middle plated layer, followed by heating as necessary, the surface layer in the present invention is obtained. There will be described an electrical component of the present invention obtained by the above manufacturing method.

FIG. 1 shows a first embodiment of an electrical component of the present invention. An electrical component 10 of the present invention has a laminate of a substrate 11, a middle layer 13 made of palladium or a palladium alloy on the substrate and a surface layer 14 made of tin or a tin alloy containing tin and a metal other than palladium formed on the middle layer 13 in this order. The electrical component 10 of the present invention can have a base layer 12 consist of the above base plated layer, under the middle layer 13.

Immediately after being formed, the middle layer 13 is equivalent to a middle plated layer made of palladium or a palladium alloy. However, palladium atoms in the middle plated layer and tin atoms in the surface plated layer mutually diffuse over time and after heating, to convert the middle layer 13 into a diffusion layer made of a tin-palladium alloy. Here, the diffusion layer can be a layer made of an intermetallic compound of tin and palladium or of a solid solution of tin and palladium, or can be a layer containing both of these. The diffusion layer can further contain one or more metals selected from an elemental metal other than tin which is contained in the surface layer, an elemental metal constituting the substrate, an elemental metal constituting the base plated layer and an elemental metal other than palladium constituting the middle plated layer. Furthermore, depending on a thickness of the middle plated layer formed during the manufacturing method, the heating conditions or a time elapsed after production of an electrical component, the middle layer 13 in the electrical component can be a layer having both a layer made of palladium or a palladium alloy and a diffusion layer.

In an electrical component of the present invention having a surface plated layer consisting primarily of tin, it is believed that such a middle layer 13 formed between the substrate 11 and the surface plated layer 14 can prevent a metal constituting the substrate 11 or the base layer 12 from diffusing into the surface plated layer to form an alloy with tin. For example, when a substrate or base layer contains copper, it is known that copper diffuses into a grain boundary of tin crystal to form an alloy (Cu₆Sn₅), which generates stress in the crystal grain boundary of tinparticles. It is, however, believed in the present invention that the diffusion layer consisting primarily of tin and palladium in the middle layer 13 can prevent formation of Cu₆Sn₅ and therefore, in the case that the substrate 11 or the base layer 12 contains copper, whisker formation can be also prevented. Again, from this reason, the middle layer 13 preferably contains a diffusion layer.

In the manufacturing method for an electrical component, a middle plated layer and a surface plated layer can be formed and heated by, for example, reflowing and annealing to form a middle layer 13 having the above diffusion layer. There are no particular restrictions to the heating conditions which can be appropriately chosen depending on the type of an electronic component produced and materials and thicknesses of the middle plated layer and the surface plated layer. For example, for a contact for a connector in which a tin surface plated layer is formed to a thickness of 3 μm on a palladium middle plated layer with a thickness of 0.05 μm, annealing can be conducted at a temperature of 80° C. or higher and lower than 232° C. for 30 sec to 180 min, to form a middle layer 13 having the above diffusion layer. Furthermore, even when heating is not conducted after forming the surface plated layer, palladium atoms in the middle plated layer and tin atoms in the surface plated layer can mutually diffuse over time to form a diffusion layer.

For further effectively preventing whisker formation, a thickness of the middle layer 13 in the electrical component 10 of the present invention is preferably 0.02 μm or more, more preferably 0.03 μm or more, further preferably 0.04 μm or more. In the light of a cost in the use of palladium, a thickness of the middle layer 13 is preferably 2 μm or less, more preferably 1 μm or less, further preferably 0.5 μm or less.

Such a surface layer 14 formed on the middle layer 13 consists of the above surface plated layer. As described above, in the electrical component 10 of the present invention, the middle layer 13 containing palladium formed between the surface layer 14 and the substrate 11 or the base layer 12 can prevent a metal constituting the substrate 11 or the base layer 12 from diffusing into the surface layer 14. In particular, when the substrate 11 or the base layer 12 contains copper, the middle layer 13 having the above diffusion layer can prevent formation of Cu₆Sn₅ which is a main cause of whisker formation in the surface layer 14. Thus, whisker formation from the surface layer 14 can be prevented.

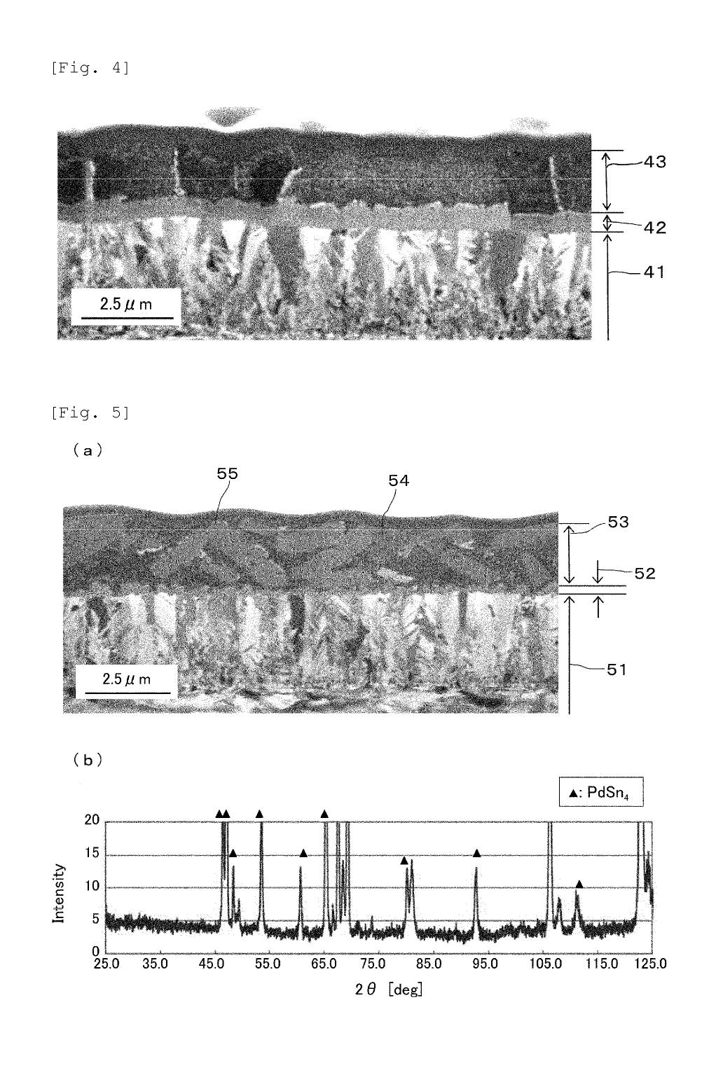

FIG. 2 is a partial cross-sectional view of a second embodiment of an electrical component of the present invention obtained by the above manufacturing method. The electrical component 20 of the present invention shown in FIG. 2 has a substrate 11 and a surface layer 24 formed on the substrate. In this embodiment, the surface layer 24 has a phase 25 made of tin or a tin alloy containing a metal other than palladium (hereinafter, sometimes referred to as “tin phase”) and an alloy phase 26 containing tin and palladium (hereinafter, sometimes referred to as “tin-palladium alloy phase”). The electrical component 20 of the present invention can have a middle layer 13 and/or a base layer 12 under the surface plated layer 24.

The tin phase 25 in the surface layer 24 is made of the same material as that of the surface plated layer used in the manufacturing method of the present invention. The tin-palladium alloy phase 26 predominantly shows a binary alloy phase of tin and palladium. The tin-palladium alloy phase 26 in the present invention can be a phase consisting of the binary alloy alone, or a ternary or more alloy further containing one or more other elements. The other metal element contained in the tin-palladium alloy phase 26 can be generally selected from, but not limited to, a metal element other than tin contained in the surface plated layer, a metal element constituting the substrate, a metal element constituting the base layer 12 and a metal element other than palladium constituting the middle layer 13.

Our investigation has implied that the binary alloy of tin and palladium constituting the tin-palladium alloy phase 26 has a orthorhombic crystal structure of PdSn₄. It is believed that such a tin-palladium alloy phase 26 formed in the surface layer 24 can relax stress generated in an interface between the substrate 11 or the base layer 12 and the surface layer 24, an energy gradient within a crystal and in a crystal grain boundary of a tin particle in the surface layer 24, and surface stress in the surface layer 24, and can, therefore, prevent whisker formation.

It is also believed that, as in the diffusion layer in the first embodiment described above, such a tin-palladium alloy phase 26 in the surface layer 24 can be effective in preventing forming an alloy of a metal constituting the substrate 11 or the base layer 12 and tin. In particular, it is significantly effective in preventing whisker formation when the substrate 11 or the base layer 12 contains copper.

The surface layer 24 in the present invention is preferably the tin phase 25 in which the tin-palladium alloy phases 26 are dispersed. That is, the surface layer 24 preferably has a sea-island structure where the tin phase 25 is a sea and the tin-palladium alloy phases 26 are islands. It is believed that the tin-palladium alloy phases 26 dispersed in the tin phase 25 can further relax an energy gradient in a tin crystal grain boundary, resulting in more effective prevention of whisker formation. Such an effect unique to the present invention is achieved by employing palladium or a palladium alloy as a metal for the middle layer. For example, it is believed that when silver is employed for the middle layer, silver diffuses within the tin plated layer and are scattered only in a tin crystal grain boundary. Therefore, an energy gradient in the tin crystal grain boundary cannot be satisfactorily relaxed, sometimes leading to whisker formation with long-term use. Furthermore, it may lead to variation in performance of an electrical component.

For forming the surface layer 24 in this embodiment, the middle plated layer and the surface plated layer are formed in this order, followed by heating as described in the manufacturing method. By appropriately choosing the heating conditions (procedure, temperature and time), elemental palladium in the middle plated layer is dispersed into the surface plated layer to form an alloy with tin. This alloy can be, as the alloy phase 26 containing tin and palladium, dispersed into the phase 25 made of tin or a tin alloy containing a metal other than palladium, to form the surface layer 24 in this embodiment.

The heating conditions for forming the surface layer 24 having the sea-island structure can be appropriately chosen depending on the type of an electronic component to be produced and materials and thicknesses of the middle plated layer and the surface plated layer, with no particular restrictions. For example, for a contact for a connector in which a tin surface plated layer with a thickness of 3 μm a palladium middle plated layer with a thickness of 0.05 μm, reflowing can be conducted at 232° C. or higher and 400° C. or lower for 1 to 120 sec, to form the surface layer 24 having a sea-island structure as shown in FIG. 2.

The electrical component 20 of the second embodiment can have a middle layer 13. The middle plated layer formed on the substrate in the manufacturing method of the present invention generally disappears by heating and over time due to diffusion of palladium atoms into the surface plated layer. But the middle plated layer can remain, for example, when its plating thickness is large. Depending on the heating conditions after forming the surface plated layer and/or a time elapsed after production, this middle layer 13 can exist as a diffusion layer as described above. When an electrical component of the present invention has the middle layer 13, a thickness of the layer is generally 2 μm or less.

In the present invention, it is preferable that in a cross-section orthogonal to the surface of the substrate 11 in the surface layers 14 and 24, there exists a continuous region with an interparticle crystal misorientation of 15° or less extending over 10 μm or more in crystal distribution of tin as determined by Electron Backscatter Diffraction (EBSD). The expression, “there exists a continuous region with an interparticle crystal misorientation of 15° or less extending over 10 μm or more” as used herein means that when a given point in a crystal orientation map (IPF) of tin particles in a cross-section of a surface layer as obtained by EBSD and another point forming a 10 μm line segment from the former point are chosen, respectively, and crystal orientation of each point on the line segment connecting these two points is determined, there exists at least one combination of two points in which the maximum of a difference in orientation between them is within 15°. The continuous region extends more preferably 20 μm or more, further preferably 50 μm or more. It is believed that when the surface plated layer has such particular crystal orientation, an energy gradient in a tin crystal grain boundary and a surface stress in the film (surface layer) can be relaxed in comparison with a tin film formed by conventional plating technique. That is, the surface layer of the present invention which has the above crystal orientation can be expected to further prevent whisker formation.

A surface layer containing a continuous region with a tin crystal misorientation of 15° or less extending over 10 μm or more as described above can be formed by forming the middle plated layer made of palladium or a palladium alloy and the surface plated layer described above, respectively, followed by heating such as reflowing and annealing. We have found for the first time that heating after plating as described above can give a surface layer having a particular crystal orientation. Although there has been described a surface layer obtained by forming a surface plated layer made of tin or a tin alloy on a middle plated layer made of palladium or a palladium alloy, such a phenomenon could occur, with no restrictions, in any system in which a surface layer has such a particular crystal orientation.

In order to prevent whisker formation in a tin plated film, heating such as reflowing has been generally used, but there have been problems that heating changes the properties of an electrical component and that solderability of a tin plated film is deteriorated. However, by employing palladium or a palladium alloy for a middle plated layer, heating causes extremely small variation in the properties of an electrical component of the present invention having a surface layer in which tin-palladium alloy phases are dispersed in a tin phase, maintaining good solderability.

A surface layer in the present invention can prevent whisker formation for a long period even under an external pressure, and can be, therefore, suitably used in an electrical component such as a terminal, a connector and a lead frame for an IC, which is press-fit into another component or deformed during a manufacturing step.

### EXAMPLES

There will be further specifically described the present invention with reference to Examples.

### Example 1

As a substrate, a phosphor bronze tape was used, in which a number of parts to be contacts for a connector are connected via a connecting member. This phosphor bronze tape was degreased and washed with an acid followed by copper strike plating (plating thickness: 0.1 μm) and then nickel plating (plating thickness: 2.0 μm) to form a base plated layer with a total thickness of about 2 μm, which was plated with palladium to give a middle plated layer with a thickness of 0.05 μm. The resulting middle plated layer was plated with tin to 3 μm to give a surface plated layer with a thickness of about 3 μm. Each of these plating processes was conducted by hoop plating, in which a palladium plating solution was PD-LF-800 from N. E. Chemcat. Corporation and a tin plating solution was SBS-M from Yuken Industry Co., Ltd. Thus, tape 1 having a number of contacts for a connector, as an electrical component of the present invention, connected to the tape was obtained. That is, tape 1 has the nickel base layer, the palladium middle layer and the tin surface layer on the substrate in this order.

Tape 1 was placed under the atmosphere of 25° C. and a relative humidity 50% RH±25% RH for 2000 hours, and its cross-section was observed as described below. By copper plating, on tape 1 was formed a protective layer, on which was further formed a tungsten deposition film. A part of the tape surface was processed by FIB (focused ion beam) to expose the cross-section of the tape. The cross-section was observed obliquely from above by an SIM (scanning ion microscope). FIG. 3 shows a microgram of the cross-section of the observed part. In FIGS. 3, 31 and 32 indicate a nickel base layer and a tin surface layer, respectively. Although the middle layer cannot be observed in FIG. 3 due to its thickness as thin as 0.05 μm, it probably exists between the nickel base layer 31 and the tin surface layer 32.

### Example 2

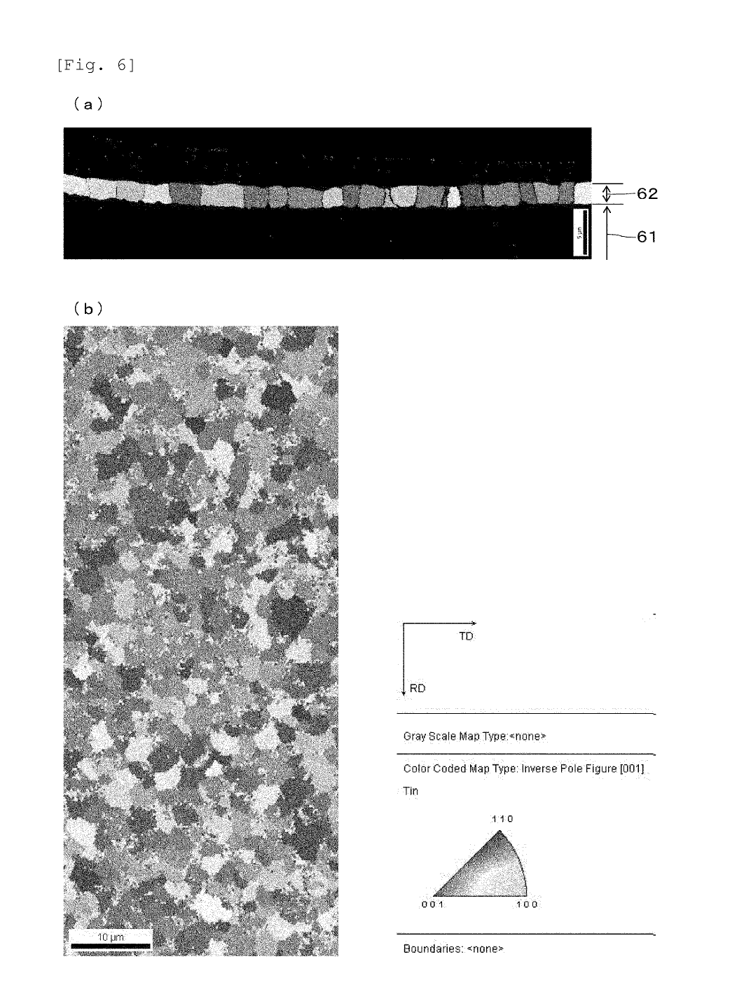

Tape 1 produced in Example 1 was placed in a simple reflow oven and annealed at a peak temperature of 225° C. for 2 min to give tape 2. The cross-section of tape 2 thus produced was observed as described in Example 1. FIG. 4 shows a microgram of the cross-section of the observed part. In FIGS. 4, 41, 42 and 43 indicate a nickel base layer, a diffusion layer as a middle layer and a tin surface layer, respectively.

### Example 3

Tape 1 produced in Example 1 was placed in a portable reflow oven and reflowed at a peak temperature of 310° C. for 2 sec to give tape 3. The cross-section of tape 3 thus produced was observed as described in Example 1. FIG. 5(a) shows a microgram of the cross-section of the observed part. In FIGS. 5(a), 51, 52 and 53 indicate a nickel base layer, a tin-palladium diffusion layer as a middle layer and a surface layer, respectively. In the surface layer 53, 54 is a tin phase and 55 is a tin-palladium alloy phase. Furthermore, the surface of tape 3 was observed by an X-ray diffractometer. FIG. 5(b) shows the X-ray diffraction pattern obtained. Thus, the presence of a peak corresponding to PdSn₄ was confirmed.

In Example 2, it was demonstrated that annealing after forming each plated layer allowed for forming the diffusion layer 42 between the surface layer 43 and the base layer 41. In Example 2, it was also demonstrated that the diffusion layer 42 was formed under the tin surface layer 43, whereas in Example 3 with the modified heating conditions, it was demonstrated that the diffusion layer 52 and the surface layer 53 having a sea-island structure in which the tin phase 54 was a sea and the tin-palladium phases 55 were islands were formed.

### Example 4

As a substrate, a phosphor bronze tape was used, in which a number of parts to be contacts for a connector are connected via a connecting member. This phosphor bronze tape was degreased and washed with an acid followed by copper strike plating (plating thickness: 0.1 μm) and then copper plating (plating thickness: 1.5 μm) to form a base layer with a total thickness of about 1.5 μm, which was plated with palladium to give a middle layer with a thickness of 0.01 The resulting middle layer was plated with tin to give a surface layer with a thickness of 3 μm. Each of these plating processes was conducted by hoop plating, in which a palladium plating solution was PD-LF-800 from N. E. Chemcat. Corporation and a tin plating solution was SBS-M from Yuken Industry Co., Ltd. Thus, tape 4 as an electrical component of the present invention was obtained, to which a number of contacts for a connector were connected.

With tape 4 thus obtained, a natural aging test was conducted as described below. Tape 4 was allowed to stand under the atmosphere of 25° C. and a relative humidity 50% RH±25% RH, and the tape was observed by field-emission-type scanning electron microscopy (FE-SEM) after 250, 500, 1000, 2000, 4000 and 5000 hours, for observing the presence of a whisker. When a whisker was observed, its length was measured and a length of the longest whisker was recorded as the maximum whisker length. The results are shown in Table 1. The number “0” in the column of the maximum whisker length in Table 1 denotes that no whiskers were observed.

### Examples 5 and 6

Tapes 5 and 6 were prepared as described in Example 4, except that a thickness of the palladium middle layer was changed as described in Table 1. Tapes 5 and 6 obtained were subjected to a natural aging test as described in Example 4. The results are shown in Table 1.

### Example 7

Tape 5 produced in Example 5 was placed in a portable reflow oven and reflowed at a peak temperature of 290° C. for 2 sec to give tape 7. Tape 7 obtained was subjected to a natural aging test as described in Example 4. The results are shown in Table 1.

### Examples 8 and 9

Tape 8 having a nickel base layer was prepared as described in Example 5, except that the base plated layer was formed by nickel plating in place of copper plating. Tape 8 thus obtained was heated as described in Example 7 to give tape 9. Tapes 8 and 9 thus obtained were subjected to a natural aging test as described in Example 4. The results are shown in Table 1.

### Comparative Example 1

Comparative tape 1 was prepared as described in Example 4 without palladium plating. Comparative tape 1 obtained was subjected to a natural aging test as described in Example 4. The results are shown in Table 1.

TABLE 1

| | | Base | | | Tin plating | | | | | | | | |
|---|---|---|---|---|---|---|---|---|---|---|---|---|---|
| | | plated | Middle plated layer | | thickness | | Maximum whisker length (μm) | | | | | | |
| | Sample | layer | Material | Thickness (μm) | (μm) | Reflowing | 0H | 250H | 500H | 1000H | 2000H | 4000H | 5000H |
| Example 4 | Tape 4 | Copper | Palladium | 0.01 | 3 | No | 0 | 0 | 10 | 20 | 20 | 20 | 20 |
| Example 5 | Tape 5 | Copper | Palladium | 0.05 | 3 | No | 0 | 0 | 0 | 0 | 0 | 9 | 15 |
| Example 6 | Tape 6 | Copper | Palladium | 0.1 | 3 | No | 0 | 0 | 0 | 0 | 0 | 0 | 0 |
| Example 7 | Tape 7 | Copper | Palladium | 0.05 | 3 | Yes | 0 | 0 | 0 | 0 | 0 | 0 | 0 |
| Example 8 | Tape 8 | Nickel | Palladium | 0.05 | 3 | No | 0 | 0 | 0 | 0 | 0 | 0 | 0 |
| Example 9 | Tape 9 | Nickel | Palladium | 0.05 | 3 | Yes | 0 | 0 | 0 | 0 | 0 | 0 | 0 |
| Comparative | Comparative | Copper | None | — | 3 | No | 0 | 10 | 30 | 50 | 50 | 71 | 87 |
| Example 1 | tape 1 | | | | | | | | | | | | |

As seen from Table 1, whiskers become longer over time in Comparative tape 1 without a middle layer whereas whisker formation over time is prevented or, if any, whisker growth is inhibited in tapes 4 to 9 of the present invention having a middle layer made of palladium. It can be also seen that a thicker palladium middle layer is more effective in preventing whisker formation.

### Example 10

A load test was conducted using tape 5 prepared in Example 5 in accordance with a sphere indentation method described in JEITA RC-5241 7.2.1. A load of 300 gf was applied to the tape by a zirconia ball indenter having a diameter of 1 mm, the status was held for 96 hours. Then, a peripheral region of an indentation formed in the tape was observed by FE-SEM for the presence of whiskers and nodules. When a whisker was observed, its length was measured. The results are shown in Table 2.

Tape 5 described above was tested for solderability as follows. A zero cross time was determined under the following conditions in accordance with a solderability testing procedure for a surface-mounted component by a balance method described in EIAJ ET-7401.

### [Test Conditions]

Pretreatment conditions: 85° C., 85% RH, saturation for 4 hours;

Measuring instrument: SWET 2100e from Tarutin Kester Co., Ltd.;

Solder: Sn-3Ag-0.5Cu;

Flux: CF-110VH-2A;

Measurement conditions: rate=2 mm/sec, immersion depth=0.2 mm, immersion time=5 sec;

Temperature: 245° C., measurement range=10 mN.

### Examples 11 and 12

Using tapes 7 and 8 prepared in Example 7 and 8, respectively, a load test was conducted as described in Example 10. The results are shown in Table 2.

### Comparable Example 2

Comparative tape 2 having a silver middle layer with a thickness of 0.3 μm was formed as described in Example 4, substituting silver plating for palladium plating. Here, a dull silver cyanate plating solution was used as a silver plating solution. Comparative tape 2 prepared was subjected to a load test as described in Example 10. The results are shown in Table 2.

### Comparative Example 3

Comparative tape 3 was prepared as described in Comparative Example 2, except that a thickness of the silver middle layer was 0.15 μm and after tinplating, heating was conducted as described in Example 7. Comparative tape 3 prepared was subjected to a load test as descried in Example 10. The results are shown in Table 2.

### Comparative Example 4

Comparative tape 4 having a nickel base layer and a silver middle layer was prepared as described in Comparative Example 2, except that the base plated layer was formed by nickel plating in place of copper plating. Comparative tape 4 prepared was subjected to a load test as descried in Example 10. The results are shown in Table 2.

TABLE 2

| | | Example | Example | Example | Comparative | Comparative | Comparative |
|---|---|---|---|---|---|---|---|
| | | 10 | 11 | 12 | Example 2 | Example 3 | Example 4 |
| Sample | | Tape 5 | Tape 7 | Tape 8 | Comparative | Comparative | Comparative |
| | | | | | tape 2 | tape 3 | tape 4 |
| Base plated | | Cu | Cu | Ni | Cu | Cu | Ni |
| layer | | | | | | | |
| Middle plated | | Pd | Pd | Pd | Ag | Ag | Ag |
| layer | | | | | | | |
| (Thickness/μm) | | 0.05 | 0.05 | 0.05 | 0.3 | 0.15 | 0.3 |
| Surface plated | | Sn | Sn | Sn | Sn | Sn | Sn |
| layer | | | | | | | |
| (Thickness/μm) | | 3 | 3 | 3 | 3 | 3 | 3 |
| Heating | | Yes | No | No | No | Yes | No |
| Number. | 1 to 5 μm | 3 | 6 | 8 | 28 | 7 | 13 |
| of | 6 to 10 μm | 8 | 0 | 2 | 21 | 15 | 21 |
| whiskers | 11 to 15 μm | 2 | 0 | 0 | 8 | 3 | 7 |
| | 16 to 20 μm | 0 | 0 | 0 | 0 | 3 | 2 |
| | 21 to 25 μm | 0 | 0 | 0 | 2 | 0 | 0 |
| | 26 to 30 μm | 0 | 0 | 0 | 0 | 1 | 0 |
| | 31 to 35 μm | 0 | 0 | 1 | 0 | 2 | 0 |
| | 36 to 40 μm | 0 | 0 | 0 | 0 | 1 | 1 |
| | 41 to 45 μm | 0 | 0 | 0 | 0 | 0 | 0 |
| | 46 to 50 μm | 0 | 0 | 0 | 0 | 0 | 0 |
| | 51 to 55 μm | 0 | 0 | 0 | 0 | 0 | 0 |
| | 56 to 60 μm | 0 | 0 | 0 | 0 | 1 | 0 |
| | 61 to 65 μm | 0 | 0 | 0 | 0 | 0 | 0 |
| | 66 to 70 μm | 0 | 0 | 0 | 0 | 0 | 0 |

| | | | | | | |
|---|---|---|---|---|---|---|
| Total number of | 13 | 6 | 11 | 59 | 33 | 44 |
| whiskers | | | | | | |
| Maximum whisker | 15.3 | 5.9 | 35.4 | 24.7 | 54.5 | 15.3 |
| length (μm) | | | | | | |
| Nodules | Many | Few | Few | Many | Many | Many |
| Zero cross time | 0.8 | 0.4 | 0.3 | 0.3 | 0.6 | 0.3 |
| (sec) | | | | | | |

From Table 2, it can be seen that Examples 10 to 12 employing a palladium middle layer, whisker formation is more effectively prevented than Comparative Examples 2 to 4 employing silver as a middle layer. This effect is more prominent when copper is used for a base layer. This demonstrates that an electrical component of the present invention having a middle layer made of palladium can prevent whisker formation even under stress. It is also demonstrated that when copper is employed for a base layer, such effect of preventing whisker formation can be more prominent. In any of Examples 10 to 12, a zero cross time is 1 sec or less, demonstrating that an electrical component of the present invention exhibits excellent solderability.

### Example 13

Tape 8 prepared in Example 8 was cut to give a contact for a connector, which was then mounted on a connector housing to give a connector 1 for a flexible printed circuit board (FPC). Connector 1 thus obtained was subjected to a connector intermateability test in accordance with the procedure described in JEITA RC-5241. Connector 1 was fit in a gold-plated FPC and the state was held for 250 hours and 500 hours, and then the presence of a whisker from the connector was observed by scanning electron microscopy (SEM). From the data obtained, the number of connectors with whiskers and a whisker incidence were calculated. The results are shown in Table 3.

### Comparative Examples 5 to 7

Comparative connectors 1 to 3 for an FPC were produced as described in Example 13, except that comparative tapes 1, 2 and 4 prepared in Comparative Examples 1, 2 and 4, respectively were used. Comparative connectors 1 to 3 obtained were subjected to an intermateability test as described in Example 13. The results are shown in Table 3.

### Comparative Example 8

A contact for a connector was produced using a tape prepared as described in Comparative Example 2 except that a thickness of the silver middle layer was changed to 0.05 μm. The product was mounted in a connector housing, to give comparative connector 4 for an FPC. Comparative connector 4 thus obtained was subjected to an intermateability test as described in Example 13. The results are shown in Table 3.

TABLE 3

| | | | | | | | Whisker incidence | |
|---|---|---|---|---|---|---|---|---|
| | | | | | Tin | | [No. of samples with | |
| | | Base | Middle plated layer | | plating | | whiskers/Total No. | |
| | | plated | | Thickness | thickness | | of samples] | |
| | Sample | layer | Material | (μm) | (μm) | Reflowing | After 250H | After 500H |
| Example 13 | Connector 1 | Nickel | Palladium | 0.05 | 3 | No | 0/240 | 0/240 |
| Comparative | Comparative | Copper | None | — | 3 | No | 4/144 | — |
| Example 5 | connector 1 | | | | | | | |
| Comparative | Comparative | Copper | Silver | 0.3 | 3 | No | 2/240 | 4/240 |
| Example 6 | connector 2 | | | | | | | |
| Comparative | Comparative | Nickel | Silver | 0.3 | 3 | No | 1/240 | 7/240 |
| Example 7 | connector 3 | | | | | | | |
| Comparative | Comparative | Copper | Silver | 0.05 | 3 | No | 1/240 | 3/240 |
| Example 8 | connector 4 | | | | | | | |

### Example 14

Here, a substrate was a copper-clad plate for an FPC where a copper sulfate foil with a thickness of 10 μm was laminated on a polyimide-based film. This copper-clad plate for an FPC was polished for surface conditioning, chemically polished, soft-etched, washed with an acid and then plated with palladium to form a middle layer with a thickness of 0.05 μm. The resulting middle layer was plated with tin to form a surface layer with a thickness of at most 5 μm. Each of these plating processes was conducted by hoop plating, in which a palladium plating solution was PD-LF-800 from N. E. Chemcat. Corporation and a tin plating solution was IF-433 from Nippon MacDermid Co., Inc., Ltd. Thus, FPC1 was obtained as an electrical component of the present invention.

FPC1 thus obtained was subjected to an intermateability test in accordance with the procedure described in JEITA RC-5241. FPC1 was fit into a gold-plated connector for an FPC and the state was held for 250 hours and then the presence of whiskers from the FPC was observed as described in Example 13. From the data obtained, the number of FPC samples with whiskers and a whisker incidence were calculated. The results are shown in Table 4.

### Comparative Example 9

Comparative FPC1 having a silver middle layer with a thickness of 0.05 μm was prepared as described in Example 14, substituting silver plating for palladium plating. Comparative FPC1 obtained was subjected to an intermateability test as described in Example 14. The results are shown in Table 4.

### Comparative Example 10

Comparative FPC2 without a middle layer was prepared as described in Comparative Example 9 without silver plating for forming a middle layer. Comparative FPC2 obtained was subjected to an intermateability test as described in Example 13. The results are shown in Table 4.

TABLE 4

| | | | | | Tin | | |
|---|---|---|---|---|---|---|---|
| | | Base | Middle plated layer | | plating | | Whisker incidence after 250H |
| | | plated | | Thickness | thickness | | [No. of samples with |
| | Sample | layer | Material | (μm) | (μm) | Reflowing | whiskers/Total No. of samples] |
| Example 14 | FPC1 | None | Palladium | 0.05 | <3 | No | 15/288 |
| Comparative | Comparative | None | Silver | 0.05 | <3 | No | 42/240 |
| Example 9 | FPC1 | | | | | | |
| Comparative | Comparative | None | None | — | <3 | No | 21/192 |
| Example 10 | FPC 2 | | | | | | |

Tables 3 and 4 demonstrate that whisker formation can be prevented in an electrical component of the present invention even under stress, for example, during fitting of a connector.

### Example 15

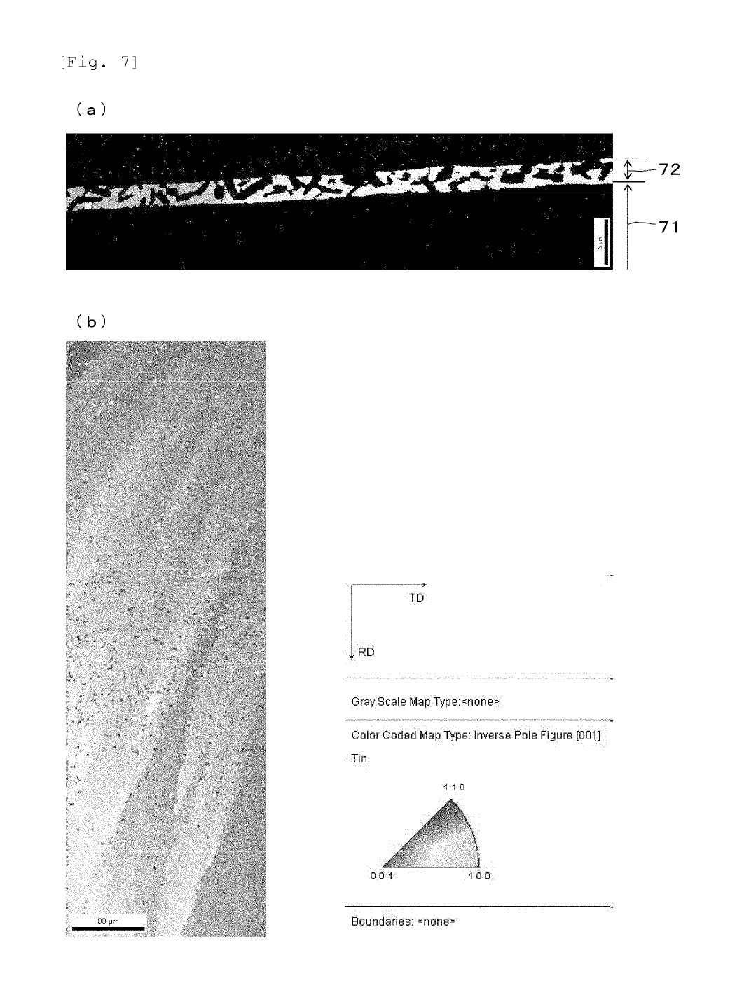

Tin crystal orientation in the cross-section and the surface of the surface plated layer in tape 8 prepared in Example 8 was determined using a crystal orientation analyzer TSL OIM series from EDAX Inc. For measurement of the tape cross-section, a sample for observing a cross-section was prepared using from an ultramicrotome EM UC6 from Leica. Tape 8 has a structure that on a substrate are formed a nickel base plated layer, a palladium middle plated layer (0.05v) and a tin surface plated layer. FIGS. 6(a) and 6(b) are a crystal orientation map (IPF) of tin in the cross-section of tape 8 and an IPF of tin in the surface, respectively. In FIGS. 6(a), 61 and 62 denote a nickel base layer and a tin surface layer, respectively.

### Example 16

Tin crystal orientation in the cross-section and the surface of the surface plated layer in tape 9 prepared in Example 9 was determined using an EBSD apparatus as described in Example 15. Tape 8 was prepared by forming a nickel base plated layer, a palladium middle plated layer (0.05 μm) and a tin surface plated layer in this order on a substrate and then heating the product. FIGS. 7(a) and 7(b) show a crystal orientation map (IPF) of tin in the cross-section of tape 9 and an IPF of tin in the surface, respectively. In FIGS. 7(a), 71 and 72 denote a nickel base layer and a tin surface layer, respectively.

FIG. 6(a) shows that in tape 8 without being heated, the surface layer is composed of tin particles with a particle size of 5 μm or less, and furthermore, a crystal grain boundary can be clearly observed. Therefore, in the IPF of a cross-section of the surface layer, a length of a region with an interparticle crystal misorientation of 15° or less is at most about a particle size of tin particles and no such continuous regions extending over 10 μm or more are observed. From the IPF of the surface in FIG. 6(b), it can be supposed that any cross-section of the surface layer has similar crystal orientation to that in FIG. 6(a).

In contrast, as shown in FIG. 7(a), the surface layer of tape 9 treated by heating had a significantly smaller number of clear crystal grain boundaries compared with FIG. 6, and crystal orientation gradually varies over a large range in the IPF. In FIG. 7(a), a crystal misorientation in both ends in a longitudinal direction was 11.5°. Thus, it can be seen that in the cross-section of the surface layer in tape 9 treated by heating, there exists a continuous region with an interparticle crystal misorientation of 15° or less extending over 50 μm or more. From the IPF of the surface in FIG. 7(b), it can be supposed that any cross-section of the surface layer has similar crystal orientation to that in FIG. 7(a). As described above, heating can provide a surface layer having a continuous region with an interparticle crystal misorientation of 15° or less extending over 10 μm or more.

### EXPLANATION OF SYMBOLS

10, 20: Electrical component
11: Substrate
12, 31, 41, 51, 61, 71: Base layer
13, 42, 52: Middle layer
14, 24, 32, 43, 53, 62, 72: Surface layer
25, 54: Phase made of tin or a tin alloy containing tin and a metal other than palladium
26, 55: Alloy phase containing tin and palladium

1. A method for manufacturing an electrical component, comprising:
forming a middle plated layer made of palladium or a palladium alloy on a substrate, and
forming a surface plated layer made of tin or a tin alloy containing a metal other than palladium on the middle plated layer.

2. The method for manufacturing an electrical component as claimed in claim 1, wherein the middle plated layer has a thickness of 0.02 to 2 μm.

3. The method for manufacturing an electrical component as claimed in claim 1, wherein the middle plated layer is formed by electrolytic plating.

4. The method for manufacturing an electrical component as claimed in claim 1, wherein the substrate is made of a material containing copper.

5. The method for manufacturing an electrical component as claimed in claim 1, further comprising heating after forming the surface plated layer.

6. The method for manufacturing an electrical component as claimed in claim 5, wherein the heating is reflowing.

7. The method for manufacturing an electrical component as claimed in claim 5, wherein the heating is annealing.

8. The method for manufacturing an electrical component as claimed in claim 1, further comprising forming a base plated layer consisting primarily of nickel or copper on the substrate before forming the middle plated layer.

9. An electrical component comprising a substrate, a middle layer made of palladium or a palladium alloy on the substrate, and a surface layer made of tin or a tin alloy containing a metal other than palladium formed on the middle layer.

10. The electrical component as claimed in claim 9, wherein the middle layer has a thickness of 0.02 to 2 μm.

11. The electrical component as claimed in claim 9, further comprising a base layer consisting primarily of nickel or copper under the middle layer.

12. An electrical component comprising a substrate and a surface layer formed on the substrate,
wherein the surface layer comprises a phase made of tin or a tin alloy containing a metal other than palladium and an alloy phase containing tin and palladium.

13. The electrical component as claimed in claim 12, further comprising a middle layer made of palladium or a palladium alloy under the surface layer.

14. The electrical component as claimed in claim 13, wherein the middle layer has a thickness of 0.02 to 2 μm.

15. The electrical component as claimed in claim 12, further comprising a base layer consisting primarily of nickel or copper under the surface layer.

16. The electrical component as claimed in claim 9, wherein the substrate is made of a material containing copper.

17. The electrical component as claimed in claim 9, wherein in a cross-section orthogonal to the substrate surface in the surface layer, there exists a continuous region with an interparticle crystal misorientation of 15° or less extending over 10 μM or more in crystal orientation distribution of tin as determined by Electron Backscatter Diffraction (EBSD).
